(19) United States
(12) Patent Application Publication
(10) Pub. No.: US 2006/0045157 A1
(43) Pub. Date: Mar. 2, 2006

(54) Semiconductor laser with expanded mode

(75) Inventors: Richard P. Ratowsky, Berkeley, CA (US); Sumesh Mani K. Thiyagarajan, Fremont, CA (US); Lars Eng, Los Altos, CA (US)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(73) Assignee: Finisar Corporation

(21) Appl. No.: 10/927,300

(22) Filed: Aug. 26, 2004

(51) Int. Cl. H01S 5/00

(52) U.S. Cl. 372/46.01; 372/45.01

(57) ABSTRACT

Systems and methods for expanding an optical mode of a laser or optical amplifier to reduce leakage current. A waveguide layer is included in a laser that optically couples with the active region. The waveguide layer is configured to expand the optical mode into the layers beneath the active region. This enables the thickness of the layers above the active region to be reduced, thereby reducing leakage current. Because the waveguide layer expanded the optical mode without substantially reducing the optical confinement of the active region, the optical loss associated with the metal contact is also reduced even though the layers between the active region and the metal contact have been thinned. In one embodiment, the threshold current is reduced.

### BACKGROUND OF THE INVENTION

1. The Field of the Invention

The present invention relates to the field of semiconductor lasers and amplifiers. More particularly, the present invention relates to laser or amplifier with an expanded optical mode to allow reduced leakage current.

2. The Relevant Technology

Lasers are some of the primary components of optical networks. They are often used in optical transceivers to generate the optical signals that are transmitted over an optical network. Lasers are also used to pump various types of optical amplifiers, such as Raman amplifiers and erbium-doped amplifiers. Edge-emitting lasers such as Fabry-Perot lasers, Distributed Feedback lasers (DFB lasers), and distributed Bragg reflector lasers (DBR lasers), etc., are examples of semiconductor lasers used in optical environments. Ridge waveguide lasers are a form of edge-emitting lasers that have an etched ridge.

One of the problems associated with ridge waveguide lasers is related to the current used to drive the laser which is determined, among other factors, by the threshold current. Threshold current is the minimum current that causes edge-emitting lasers, including ridge waveguide lasers, to lase. When a laser is at or above the threshold current, stimulated emission results in laser light. One of the factors that affects the threshold current is leakage current. Leakage current, for example, is the current that escapes into the semiconductor layer(s) between the metal contact and the active region.

In other words, the thickness of these semiconductor layer(s) between the metal contact and the active region impacts the leakage current that escapes into these semiconductor layer(s). The problem with thinning these semiconductor layer(s) to reduce the leakage currents unfortunately results in an optical loss that is associated with the interaction of the optical mode of the semiconductor laser with the metal contact deposited on the top surface of the laser. As a result of the optical loss, the threshold current of the semiconductor laser is increased even though the leakage current was reduced by thinning. Often, the increased optical loss is worse for longer wavelength lasers (for example, worse for 1550 nm vs. 1310 nm).

In other words, a thick layer between the active region and the metal contact of the semiconductor laser is associated with a leakage current. If the thickness of this layer is reduced, then the lossy metal contact interferes with the optical mode. There is therefore a balance between the thickness of the semiconductor layer(s) and the optical loss to the metal contacts that is performed to minimize the threshold current of the laser.

One way to approach this problem is to control lateral current confinement by first etching to the active region and then epitaxially growing current-blocking layers to form a buried heterostructure (BH) that confines lateral leakage current. While the problem of excessive current leakage may be reduced, the laser is no longer a simple ridge waveguide structure. In other words, the buried heterostructure increases the complexity of growth, processing and fabrication. As a result, the cost of the laser is likewise increased.

In addition, there are applications, such as Dense Wavelength Division Multiplexing (DWDM), Coarse Wavelength Division Multiplexing (CWDM) and Raman pumps, where DFB lasers with highly precise lasing wavelengths are required. The lasing wavelength of a DFB laser may be determined by the pitch of a grating layer and the effective index of the lasing mode. Since the effective index is much less sensitive to lateral dimensions for a ridge waveguide laser compared with a BH laser, very high yields and low cost targets can be achieved using a ridge waveguide structure.

### BRIEF SUMMARY OF THE INVENTION

These and other limitations are overcome by embodiments of the present invention, which relate to systems and methods for expanding an optical mode of semiconductor devices such as lasers including ridge waveguide lasers and optical amplifiers. Embodiments of the invention can reduce a leakage current often associated with ridge waveguide lasers and other types of semiconductor lasers and/or reduce the thickness of the semiconductor layer(s) between the active region and the metal contact.

In one embodiment, a waveguide layer is added to the laser. The waveguide layer is typically positioned below the active region. An n-type semiconductor layer having a refractive index that is lower than both the active region and the waveguide layer is typically located between the active region and the waveguide layer. The waveguide layer optically couples with the active region and draws the optical mode into the semiconductor layer separating the active region and the waveguide layer. The refractive index of the active region is generally higher than the refractive index of the waveguide layer.

The waveguide layer is designed to optically couple with the active region such that the optical confinement of the optical mode in the active region is not substantially reduced. In one example, the waveguide layer reduces the confinement of the optical mode by less than 2 percent. Because the waveguide layer expands the optical mode of the laser, the semiconductor layer(s) between the active region and the metal contacts can be reduced or thinned without the optical loss to the metal contacts experienced in conventional devices.

Thinning these semiconductor layer(s) increases the lateral resistance of the layers and therefore reduces leakage current. As a result, more of the current flows to the active region. In some embodiments, the threshold current of the laser is reduced. In addition, the lossy metal contact of the semiconductor laser does not result in appreciable optical loss when the optical mode is expanded by the waveguide layer even though thickness of the semiconductor layer(s) between the metal contact and the active region have been reduced.

Additional features and advantages of the invention will be set forth in the description which follows, and in part will be obvious from the description, or may be learned by the practice of the invention. The features and advantages of the invention may be realized and obtained by means of the instruments and combinations particularly pointed out in the appended claims. These and other features of the present invention will become more fully apparent from the following description and appended claims, or may be learned by the practice of the invention as set forth hereinafter.

### BRIEF DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1A illustrates an example of a perspective ridge waveguide laser that includes a layer to expand the optical mode of the laser;

FIG. 1B illustrates an example of an active region that includes a plurality of quantum wells separated by barrier layers;

FIG. 2 illustrates an example of leakage current in a conventional ridge waveguide laser;

FIG. 3A illustrates an example of leakage current in a ridge waveguide laser with a waveguide layer to expand the optical mode of the laser;

FIG. 3B illustrates a ridge waveguide laser that includes a grating layer to form a distributed feedback laser;

FIG. 4 illustrates another embodiment of the waveguide layer used to expand the optical mode of a semiconductor laser; and

FIG. 5 illustrates that embodiments of the waveguide layer can be either wavelength dependent or wavelength independent.

### DETAILED DESCRIPTION OF THE PREFERRED EMBODIMENTS

Embodiments of the present invention relates to systems and methods for expanding an optical mode of a semiconductor laser and/or an optical amplifier. Edge emitting lasers including ridge waveguide lasers have one or more semiconductor layers between the active region and the metal contact. As previously stated, the threshold current of the laser is affected by leakage current lost into these semiconductor layers. At the same time, reducing the thickness of these semiconductor layers can result in the lossy metal contact interfering with the optical mode of the laser. As a result, one of the disadvantages of leakage current is an increased threshold current.

Although embodiments of the invention are described in terms of a semiconductor laser, one of skill in the art can appreciate that the same or similar structure can operate as an optical amplifier.

Embodiments of the present invention expand the optical mode of a semiconductor laser. By expanding the optical mode of the laser, the thickness of the semiconductor layers (referred to herein as “spacer layers”) between the active region and the metal contact can be reduced without the deleterious effects previously described. In other words, the leakage current is reduced because the thickness of the spacer layers is reduced. Further, the expanded optical mode reduces the effect of the lossy metal contact on the optical mode. Advantageously, the threshold current of the laser may be reduced.

The optical mode of the laser may be expanded by adding an epitaxial waveguide layer beneath the active region. The added epitaxial waveguide layer optically couples with the active region and expands the optical mode such that the thickness of the spacer layers between the active region and the metal contact can be reduced. Advantageously, the overlap of the optical mode with the active region is not appreciably reduced by the waveguide layer. The optical mode is reshaped or expanded as further described below. By reshaping the optical mode or by expanding the optical mode, optical losses to the metal contact are substantially reduced.

If the overlap of the optical mode with the active region were reduced, then the threshold current requirements of the laser would increase, whereas embodiments of the invention can reduce the threshold current. In one embodiment, the confinement of the optical mode to the active region is reduced by less than 2 percent.

The principles of the invention may be extended to various material systems and combinations of materials. For example, GaAs material systems may include AlGaAs, AlGaInP, AlGaInAsP, GaInAsN, GaInAsNSb, AlGaInAsNSbP, InGaAsSb, AlInAsSb, and the like or any combination thereof. Similarly, an InP, BaSb, and InAs are other examples of material systems that may be used. One of skill in the art can appreciate that embodiments of the invention can use other semiconductor materials including binary, ternary, and quaternary semiconductor compounds.

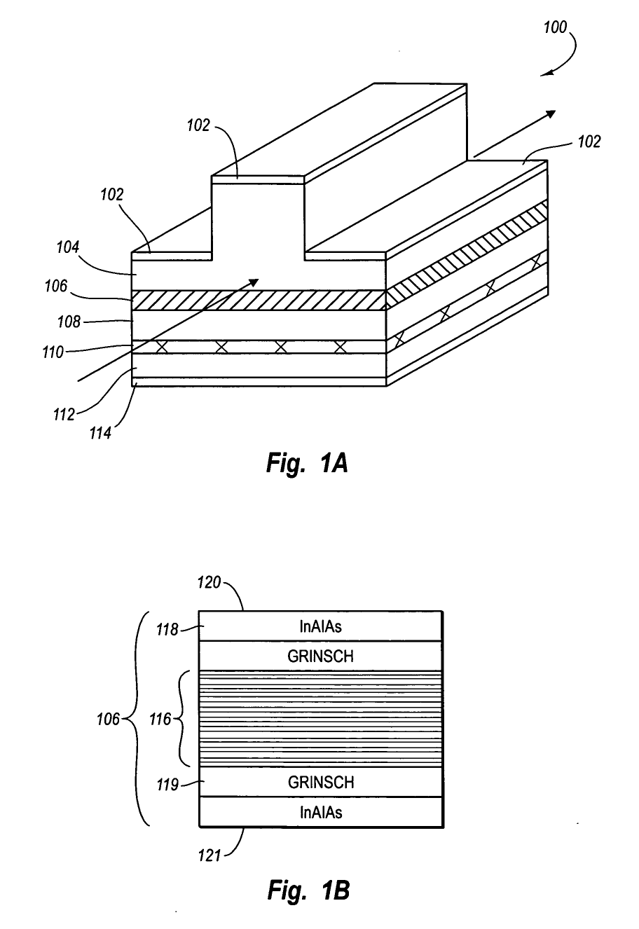

FIG. 1A illustrates a perspective view of a ridge waveguide laser. The semiconductor laser 100 is an edge emitting laser in this example, but one of skill in the art can appreciate that the laser 100 may be a Fabry-Perot laser, a DFB laser, a DBR laser, and the like. The laser 100 includes a top contact 102 that is typically formed of metal or other suitable material. The bottom contact 114 is also usually formed of metal or other suitable material.

The laser 100 includes a substrate 112. A waveguide layer 110 is formed or grown on the substrate 112 and is formed from a semiconductor material. An n-type semiconductor layer 108 is formed on the waveguide layer 110. The active region 106 is formed on the n-type semiconductor layer 108. A p-type semiconductor layer 104 is next formed on the active region 106. Lastly, the metal contact 102 is formed on p-type semiconductor layer 104.

In one embodiment, the substrate 112 is InP. In some embodiments, an InP buffer layer may also be formed on the substrate 112. The waveguide layer 110 may have a thickness on the order of 120 nanometers and may be formed from InGaAsP with a photoluminescence peak wavelength of about 1345 nanometers. The n-type semiconductor layer 108 is formed from InP and may be 1.3 micrometers thick.

The active region 106 can be a uniform semiconductor material or may include quantum wells, quantum wires, or quantum dots. The individual layers in the active region 106 may be strained or lattice matched, and intentionally doped or undoped. In one specific example illustrated in FIG. 1B, the active region 106 is a multi-quantum well structure 116 having six wells interleaved with seven (7) barrier layers. The material used in this embodiment of the multi-quantum well structure 116 is InGaAlAs. Each quantum well has a thickness of 6 nanometers and has a 1.78% compressive strain. The barrier layers are 7 nanometers thick and 0.59% tensile strained, with an aluminum content such that the bandgap is 1270 nanometers. The photoluminescense peak of the active region is 1550 nanometers.

The active region 106 may also include graded index separate confinement heterostructure (GRINSCH) layers 118, 119, which are also illustrated in FIG. 1B. The GRINSCH layers 118, 119 sandwich the multi-quantum well structure 116 and are each on the order of 120 nanometers thick. For each GRINSCH layer 118, 119, the bandgap ramps down from 960 nanometers to 850 nanometers moving away from the multi-quantum well structure 116. Each GRINSCH layer 118, 119 is followed by a layer of InAlAs 120, 121 that is 50 to 100 nanometers thick. In one embodiment, these layers are not doped.

Thus the InAlAs layer 121 would be formed on the layer 108. The p-type semiconductor layer 104 is formed on the other InAlAs layer 120 in this example. The p-type semiconductor layer 104 is typically formed from InP. The layer 104 is also an example of a spacer layer. To complete the laser 100, a ridge waveguide process is performed in the layer 104 to form a ridge in the laser 100. The metal contact may be deposited or formed after the ridge is formed in one embodiment.

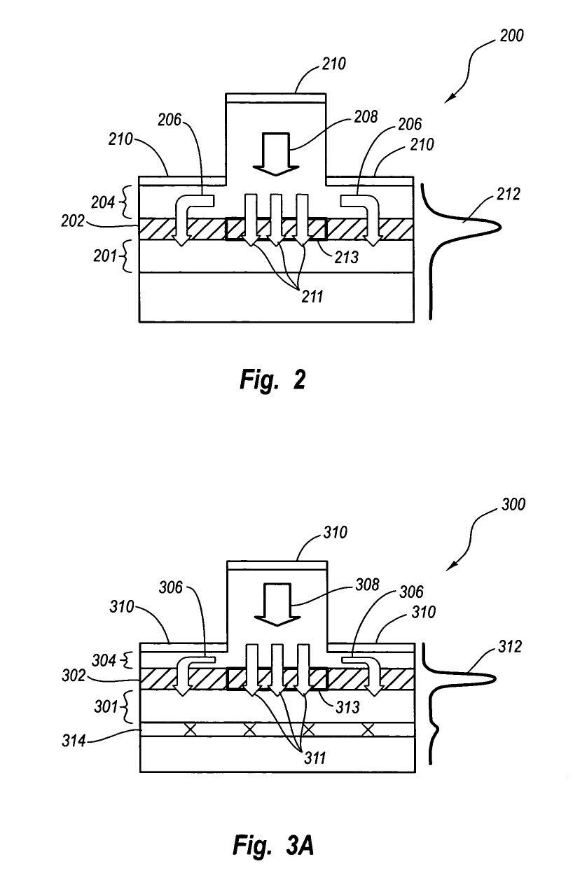

FIG. 2 is a side view of a ridge waveguide laser that does not include a layer to expand the optical mode. In FIG. 2, the active region 202 is sandwiched between an n-type semiconductor layer 201 and a p-type semiconductor layer 204. The layer 204 has a thickness that is associated with a leakage current 206. The measured threshold current 208 of the laser 200 is the sum of the intrinsic threshold current 211 and the leakage current 206. Current is most effective in the active region 213 and the thickness of the semiconductor layer(s) 204 between the active region 202 and the contact 210 permits leakage current 206.

FIG. 2 also illustrates the optical mode 212 of the laser 200 in the vertical direction. The mode 212 is primarily confined to the active region 202. If the optical mode 212 does not substantially overlap the active region, the modal gain of the laser 200 is reduced and the threshold requirements of the laser are increased.

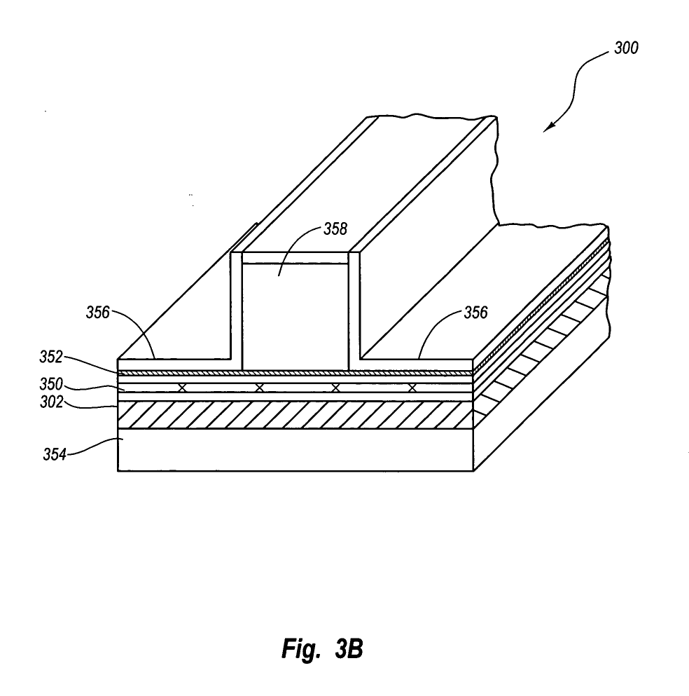

FIG. 3A illustrates an embodiment of a laser that includes a semiconductor layer for expanding the optical mode of laser. As illustrated in FIG. 3A, the layer 304 is thinner than the corresponding layer 204 of the laser 200. The thinness of the layer 304 increases the lateral resistance of the layer 304 and inhibits current flow in the lateral direction. In other words, the leakage current 306 is reduced compared to the leakage current 206. Because the leakage current 306 is reduced, more of the current 308 flows into the active region 302 and in particular the region 313 of the active region 302. For at least this reason, the threshold current of the laser 300 may be lowered.

The waveguide layer 314 reshapes the optical mode 312 of the laser 300 such that the overlap of the electric field with the metal contact 310 can be reduced to a nominal value (the value associated with the thick layer 204 in FIG. 2, for example). In this example, however, the layer 304 is thinner than the layer 204 while still reducing the overlap of the electric field to a nominal value. The optical mode 312 further experiences lower overall loss because the layer 301 is, in one embodiment, n-type InP, which has lower free-carrier loss than the p-type material of the layer 304. Thus, the optical mode 312 is drawn further into the n-type layer 301 by the mode expanding or waveguide layer 314.

Although the waveguide layer 314 draws the optical mode into the layer 301, the overlap of the optical mode with the active region 302 is not reduced appreciably, or the modal gain would decrease and the threshold requirements would increase. In one embodiment, the confinement of the optical mode to the active region is reduced less than 2 percent by the waveguide layer 314. In some embodiments, the threshold requirements (including current threshold) of the laser 300 with the mode expanding or waveguide layer 314 is lower than the threshold of a conventional laser.

The waveguide layer 314 (and the waveguide layer 110 in FIG. 1) is typically formed from a semiconductor material. In an InP based laser or optical amplifier, the waveguide may be InGaAsP lattice matched to InP. The specific composition or other parameters of the waveguide layer 110 can be altered as described below to improve the performance.

The layer 314 has several parameters that can be adjusted or controlled that has an impact on a strength of coupling of the optical mode between the waveguide layer 314 and the active region 302. The strength of coupling determines how the optical mode is expanded by the waveguide layer 314. When the waveguide layer 314 is used to expand the optical mode, the waveguide layer 314 is usually designed to couple with the first optical mode or primary optical mode of the laser without substantially reducing the confinement of the optical mode as illustrated in FIG. 3A.

Various parameters of the mode expanding or waveguide layer 314 can be adjusted to impact the mode confinement or the expansion of the optical mode. Examples of parameters include, but are not limited to, thickness of the waveguide layer, location of the waveguide layer with respect to the active region (thickness of the layer 301, for example), material composition or formulation of the waveguide layer, refractive index of the waveguide layer, modal index of the waveguide layer, and any combination thereof.

FIG. 3B illustrates another embodiment where a waveguide layer 350 is optionally located above the active region 302. In an alternative embodiment, a laser 300 may include a waveguide layer both above and/or below the active region. FIG. 3B also illustrates a grating 352 for an embodiment where the laser 300 is a DFB laser.

The typical thickness of the waveguide layers (such as the waveguide layers 314 in FIG. 3A and layer 350 in FIG. 3B) are 50 nm-200 nm for single layer, up to several microns for multiple layers with low average index. Spacer layers without waveguide layers are typically 150-250 nm, with the waveguide layer, these dimensions are reduced by half. FIG. 3B also illustrates that the laser 300 includes a dielectric layer 356. A metal contact may be formed on the ridge 358 and may also cover the dielectric layer 356.

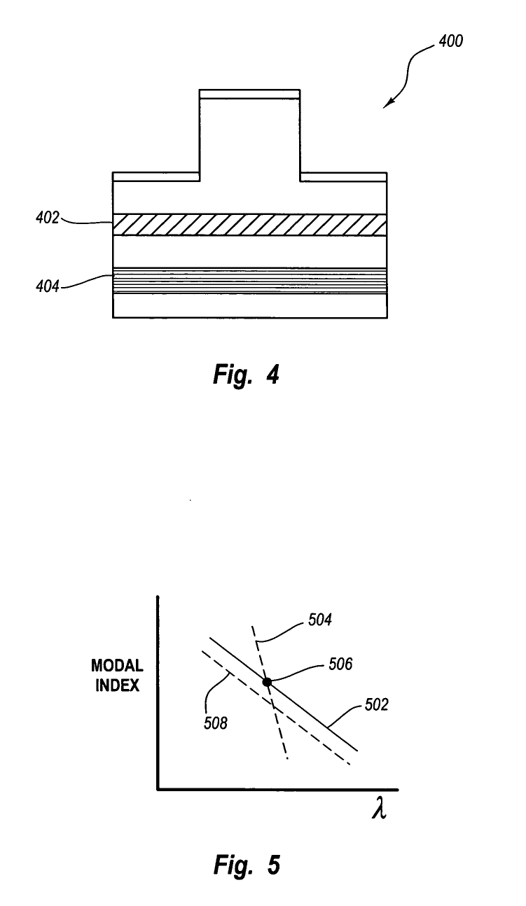

Another parameter may be the number and type of layers in the waveguide layer. FIG. 4, for example, illustrates a waveguide layer 404 that includes multiple layers. The multiple layers may be distributed Bragg layers, for example. One of skill in the art can also appreciate that the formulation of the active region can also be adjusted to impact the mode confinement and/or the material gain of the active region.

The effect of the waveguide layer, such as the waveguide layers 110, 314, and 404, can be either wavelength dependent or wavelength independent. FIG. 5 illustrates plots of the modal index of a semiconductor laser such as the laser 300 or the laser 100 as a function of the wavelength. The curve 502 represents the modal index of the active region. The curve 504 represents an example where the coupling of the waveguide layer to the active region is wavelength dependent. At the point 506, the waveguide layer strongly couples with the active region and corresponds to a dip in the gain curve.

In contrast, the curve 508 corresponds to an example of a waveguide layer where the coupling of the waveguide layer to the active region is independent of the wavelength. The strength of the confinement of the optical mode to the active region decreases as the curve 508 moves closer to the curve 502. Thus, the coupling of the waveguide layer with the active region can be configured to be wavelength dependent or wavelength independent. The strength of the coupling can also be controlled by formulating the waveguide layer and/or the active region as previously discussed. One or more of the parameters associated with the waveguide layer are typically configured such that the mode confinement is not reduced by more than 2%.

Another advantage of embodiments of the present invention is to improve the farfield of a semiconductor laser. Expanding the optical mode of a laser with the waveguide layer results in a reduction in the angular divergence of the laser in the farfield, and a reduced asymmetry in the beam (vertical divergence angle divided by horizontal divergence angle). This improves coupling efficiency with an optical fiber and corresponds to relaxed requirements on the output power of a laser, and/or any intermediate coupling optics. By relaxing the requirements on coupling optics, the cost of an optical subsystem can be further reduced. In one embodiment, the vertical divergence is smaller than the vertical divergence of a conventional laser by 14 degrees and the asymmetry is reduced by a factor of approximately 2.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A semiconductor device comprising:
a waveguide layer arranged over a substrate;
a first semiconductor layer arranged over the waveguide layer;
an active region arranged over the first semiconductor layer, wherein the waveguide layer expands an optical mode of the active region into at least the first semiconductor layer;
a second semiconductor layer formed on the active region, the second semiconductor layer having a thickness determined by at least the waveguide layer; and
a contact formed on the second semiconductor layer.

2. A semiconductor device as defined in claim 1, wherein at least the second semiconductor layer is etched to form a ridge.

3. A semiconductor device as defined in claim 1, wherein a strength of coupling between the waveguide layer and the active region reduces a confinement of the optical mode in the active region by less than a particular percentage.

4. A semiconductor device as defined in claim 3, wherein the particular percentage is 2 percent.

5. A semiconductor device as defined in claim 3, wherein the strength of coupling is related to one or more of:
a thickness of the waveguide layer;
a location of the waveguide layer with respect to the active region;
a material composition of the waveguide layer;
a refractive index of the waveguide layer; and
a modal index of the waveguide layer.

6. A semiconductor device as defined in claim 1, wherein the waveguide layer comprises InGaAsP;

7. A semiconductor device as defined in claim 1, wherein the waveguide layer has a thickness greater than 100 nm.

8. A semiconductor device as defined in claim 1, wherein the waveguide layer has a photoluminescence peak wavelength of about 1345 nm.

9. A semiconductor device as defined in claim 1, wherein the active region has a photoluminescence peak of about 1550 nm.

10. A semiconductor device as defined in claim 1, wherein a strength of coupling of the optical mode between the active region and the waveguide layer is wavelength dependent.

11. A semiconductor device as defined in claim 1, wherein the waveguide layer is one of above the active region or below the active region.

12. A semiconductor device as defined in claim 1, further comprising a grating layer arranged over the active region.

13. A semiconductor device as defined in claim 12, wherein the grating layer is formed on a ridge structure formed over the active region.

14. A semiconductor device as defined in claim 1, wherein a strength of coupling of the optical mode between the active region and the waveguide layer is wavelength independent.

15. A semiconductor device as defined in claim 1, wherein the waveguide layer further comprises a plurality of distribute Bragg reflector layers.

16. A semiconductor device as defined in claim 1, wherein the semiconductor device is at least one of a laser or an optical amplifier.

17. A semiconductor device comprising:
an waveguide layer arranged over a substrate;
an active region arranged over the waveguide layer, wherein a strength of coupling between the waveguide layer and the active region expands an optical mode of the active region;
a semiconductor layer arranged over the active region, the semiconductor layer having a thickness that is related to at least the waveguide layer.

18. A semiconductor device as defined in claim 17, wherein the thickness of the semiconductor layer affects a leakage current of the laser.

19. A semiconductor device as defined in claim 17, wherein the waveguide layer expands the optical mode without reducing a confinement of the mode by more than a particular percentage.

20. A semiconductor device as defined in claim 19, wherein the particular percentage is 2 percent.

21. A semiconductor device as defined in claim 17, further comprising a metal contact arranged over the semiconductor laser, wherein the waveguide layer expands the optical mode such that the optical loss of the optical mode to the metal contact is reduced.

22. A semiconductor device as defined in claim 17, wherein the strength of coupling is related to one or more of:
a thickness of the waveguide layer;
a location of the waveguide layer with respect to the active region;
a material composition of the waveguide layer;
a refractive index of the waveguide layer; and
a modal index of the waveguide layer.

23. A semiconductor device as defined in claim 17, wherein the waveguide layer comprises a plurality of distributed Bragg reflector layers.

24. A semiconductor device as defined in claim 17, wherein the strength of coupling is wavelength dependent.

25. A semiconductor device as defined in claim 17, wherein the strength of coupling is wavelength independent.

26. A semiconductor device as defined in claim 17, wherein the semiconductor device is at least one of a laser and an optical amplifier.

27. A semiconductor device as defined in claim 17, further comprising a ridge structure having a grating layer to form a distributed feedback layer, the ridge structure formed over the active region.

28. A method for reducing a leakage current in a semiconductor laser, the method comprising:
arranging a waveguide layer over a substrate;
arranging an active region over the waveguide layer;
arranging a semiconductor layer over the active region; and
determining a thickness of the semiconductor layer based on a strength of coupling between the waveguide layer and the active region, wherein the thickness determines a magnitude of the leakage current.

29. A method as defined in claim 28, further comprising forming a second semiconductor layer between the active region and the waveguide layer.

30. A method as defined in claim 28, further comprising etching the semiconductor layer to form a ridge structure in the semiconductor laser.

31. A method as defined in claim 28, wherein determining a thickness of the semiconductor layer based on a strength of coupling between the waveguide layer and the active region further comprises at least one of:
determining a thickness of the waveguide layer;
determining a distance between the waveguide layer and the active region;
selecting a material composition of the waveguide layer;
selecting a modal index of the waveguide layer such that the strength of coupling is wavelength independent; and selecting a modal index of the waveguide layer such that the strength of coupling is wavelength dependent.

32. A method as defined in claim 28, further comprising arranging a metal contact over the semiconductor layer, wherein the waveguide layer expands an optical mode of the semiconductor laser such that an optical loss of the metal contact is reduced.

33. A method as defined in claim 28, further comprising:
forming a ridge structure over the active region; and
forming a grating layer on at least the ridge structure.
